(19) United States
(12) Patent Application Publication
(10) Pub. No.: US 2005/0145920 A1
(43) Pub. Date: Jul. 7, 2005

(54) Non-volatile memory and fabricating method thereof

(76) Inventors: Ko-Hsing Chang, Hsinchu (TW); Chiu-Tsung Huang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/707,650

(22) Filed: Dec. 30, 2003

(51) Int. Cl. H01L 29/788

(52) U.S. Cl. 257/315

(57) ABSTRACT

A non-volatile memory structure and a fabricating method thereof are described. In the fabricating method, a mask layer is formed over a substrate first. A trench is formed in the mask layer and the substrate, and then a tunnel dielectric layer is formed in the trench. A floating gate is formed inside the trench, and then the mask layer is removed. A high-voltage doped region is formed in the substrate on one side of the floating gate, serving as a first source/drain region and a control gate simultaneously. A second source/drain region is then formed in the substrate on the other side of the floating gate.

### BACKGROUND OF INVENTION

1. Field of the Invention

The present invention relates to a structure of a semiconductor device and a fabricating method thereof. More particularly, the present invention relates to a structure of a non-volatile memory and a fabricating method thereof.

2. Description of the Related Art

Electrically programmable and erasable non-volatile memory is a small, fast access, large capacity memory that retains data even when the power is cut off. Therefore, electrically programmable and erasable non-volatile memory has become a mainstream product among portable memory media. In general, such a non-volatile memory cell includes a floating gate, a control gate and a pair of source/drain regions. An additional select gate may also be installed next to the floating gate to form a split-gate structure to prevent problems caused by over-erase.

FIG. 6 shows a schematic cross-sectional view of the structure of a conventional electrically programmable and erasable non-volatile memory. As shown in FIG. 6, the non-volatile memory includes a substrate 600, a pair of floating gates 602 on the substrate 600 each having a thermal oxidation layer 604 on the top and a spacer 606 on the sidewall, a high-voltage doped region 608, a pair of select gates 610 and a pair of source/drain regions 612. The high-voltage doped region 608 is located in the substrate 600 between the floating gates 602. The high-voltage doped region 608 overlaps with the bottoms of the two floating gates 602, so as to serve as a common source/drain region as well as a control gate. The select gates 610 are located on the outward-facing sides of the floating gates 602, and each select gate 610 is isolated from the corresponding floating gate 602 by the thermal oxide layer 604 and the spacer 606.

Although the aforementioned structure is being used widely, the following problems are frequently encountered. Since the high-voltage doped region 608 overlaps with only the bottom of each floating gate 602, the gate coupling ratio (GCR) between them is low. With a low GCR, programming and data erasure must be carried out with a high voltage rendering the miniaturization of memory device difficult. Furthermore, because the floating gate 602 has a considerable height, the select gates 610 are difficult to etch in a subsequent patterning process. Moreover, the high-voltage doped region 608 must have a sufficiently low resistivity, but the depth of the high-voltage doped region 608 must not be too large to cause a serious punch through leakage. In other words, there is a limit to the extent of width reduction for the high-voltage doped region 608, and thus the degree of device miniaturization is restricted.

### SUMMARY OF INVENTION

Accordingly, at least one object of the present invention is to provide a non-volatile memory and a fabricating method thereof wherein a portion of the floating gate is buried in the substrate and the high-voltage doped region is positioned adjacent to a side surface of the floating gate.

To achieve these and other advantages and in accordance with the purpose of the invention, as embodied and broadly described herein, the invention provides a method for fabricating a non-volatile memory. Firstly, a mask layer is formed over a substrate. A trench is formed in the mask layer and the substrate. Thereafter, a tunnel dielectric layer is formed on the interior surface of the trench, and then a floating gate is formed in the trench. After the mask layer is removed, a high-voltage doped region is formed in the substrate on one side of the floating gate. The high-voltage doped region simultaneously serves as a first source/drain region and a control gate. A second source/drain region is formed in the substrate on the other side of the floating gate. Furthermore, a select gate can be formed between the floating gate and the second source/drain region. The select gate is isolated from the substrate by a gate dielectric layer.

This invention also provides another method for fabricating a non-volatile memory, wherein a common high-voltage doped region is formed in the substrate between a pair of floating gates. In addition, a select gate is formed on the outward-facing side of each floating gate, and a source/drain region is formed on the outward-facing side of each select gate. Here, the outward-facing side of a floating gate refers to the opposite side of the inward-facing side defined between the pair of floating gates.

This invention also provides a non-volatile memory structure. The structure includes a substrate, a floating gate, a high-voltage doped region serving as a first source/drain region and a control gate, and a second source/drain region. The substrate has a trench therein, which is lined with a tunnel dielectric layer. The floating gate fills up the trench and protrudes above the substrate. The high-voltage doped region is located in the substrate on one side of the floating gate. The second source/drain region is located in the substrate on the other side of the floating gate. Furthermore, a select gate can be set up between the floating gate and the second source/drain region, being isolated from the substrate by a gate dielectric layer.

In another non-volatile memory structure of this invention, a common high-voltage doped region is located in the substrate between a pair of floating gates. In addition, a select gate is set up on the outward-facing side of each floating gate and a source/drain region is set up on the outward-facing side of each select gate.

In this invention, the high-voltage doped region that serves also as a control gate further overlaps with a side surface of the floating gate. Hence, the gate-coupling ratio (GCR) between the control gate and the floating gate is greatly increased. Furthermore, because a portion of the floating gate is buried inside the substrate, the height of the floating gate relative to the substrate surface is reduced. With a reduction in the height of the floating gate, subsequent etching of the select gate is easier to carry out and faster to complete. Moreover, because the bottom portion of the floating gate is buried deep in the substrate, the depth of the high-voltage doped region can be increased to reduce the resistivity without increasing the punch-through leakage current. Consequently, the width of the high-voltage doped region can be reduced to produce a memory device with a higher degree of integration.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1 through 5 schematically show the steps for fabricating a non-volatile memory according to an embodiment of this invention in a cross-sectional view.

FIG. 5 also illustrates a schematic cross-sectional view of a non-volatile memory structure according to the embodiment of this invention.

FIG. 6 illustrates a schematic cross-sectional view of a conventional electrically programmable and erasable non-volatile memory.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

FIGS. 1 through 5 schematically show the steps for fabricating a non-volatile memory according to the embodiment of this invention in a cross-sectional view. Referring to FIG. 1, a pad oxide layer 102 and a silicon nitride hard mask layer 104 are sequentially formed over a substrate 100. The silicon nitride hard mask layer 104 is formed by performing a low-pressure chemical vapor deposition (LPCVD) process, for example. Thereafter, a pair of trenches 106 is formed in the silicon nitride hard mask layer 104 and the substrate 100. The trenches 106 are formed, for example, by performing a photolithographic process followed by an anisotropic etching process.

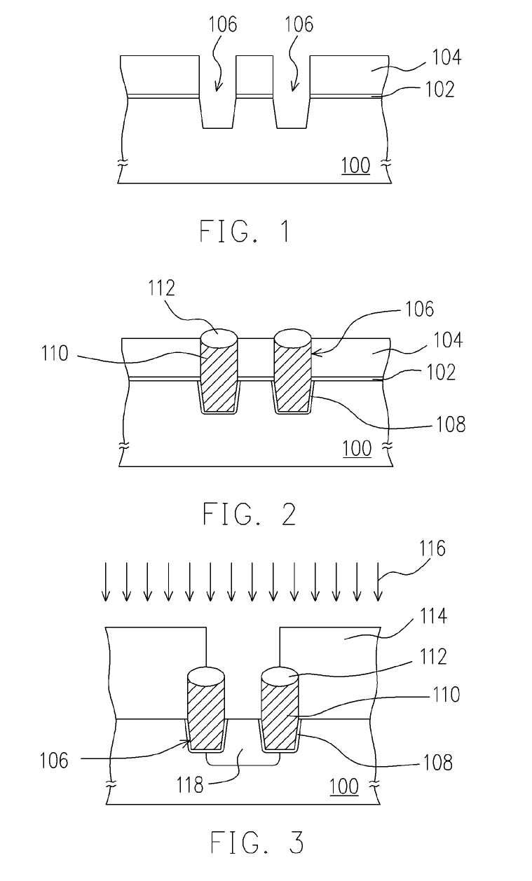

Referring to FIG. 2, a tunnel oxide layer 108 is formed on the interior surfaces of each trench 106 with thermal oxidation, for example. Thereafter, a conductive material, such as doped polysilicon, is deposited to fill the trenches 106 and thereby form a pair of floating gates 110. A heavy thermal oxidation process is then carried out to form a thermal oxide layer 112 on each floating gate 110. The thermal oxide layer 112 is thicker at the center and thinner toward the edge, so that a sharp edge is produced at the top corner of each floating gate 110.

Referring to FIG. 3, the silicon nitride hard mask layer 104 and the pad oxide layer 102 are removed. Another mask layer 114 is formed over the substrate 100 exposing the substrate 100 between the two floating gates 110. The mask layer 114 is a photoresist layer, for example. Thereafter, an ion implantation 116 is carried out to form a high-voltage doped region 118 in the substrate between the two floating gates 110. The high-voltage doped region 118 simultaneously serves as a common source/drain region and a control gate for the two-cell memory unit. After the mask layer 114 is removed, an annealing process is carried out to repair the damaged lattice resulting from the implantation and to expand the high-voltage doped region 118 into the substrate 100 under the bottom of each floating gate 110.

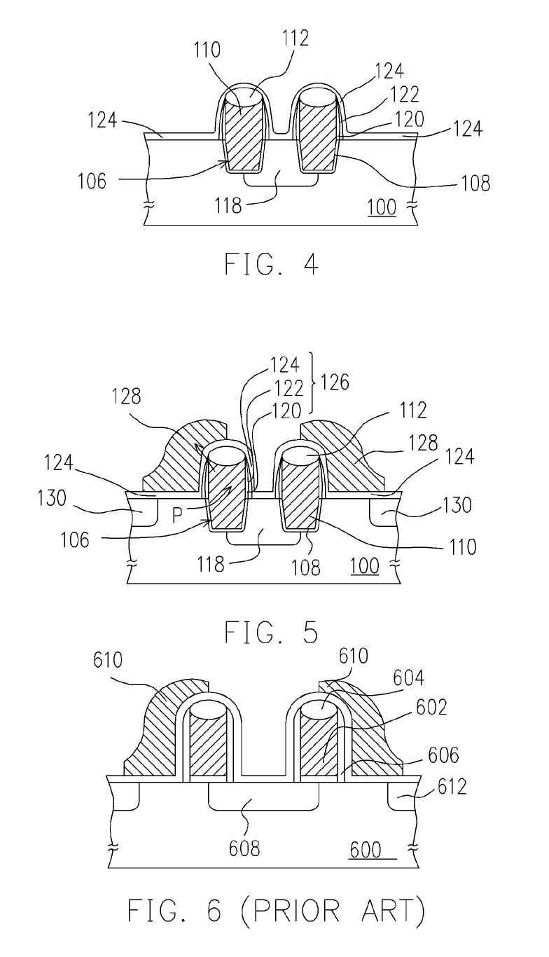

Referring to FIG. 4, a silicon oxide layer 120 and a silicon nitride layer 122 are sequentially formed on the exposed sidewall of each floating gate 110 to form an oxide/nitride (ON) spacer. The silicon oxide layer 120 is formed, for example, by depositing a conformal silicon oxide layer and then anisotropically etching the conformal silicon oxide layer. The silicon nitride layer 122 is formed, for example, by depositing a conformal silicon nitride layer and then anisotropically etching the conformal silicon nitride layer. Thereafter, a conformal silicon oxide layer 124 is formed over the substrate 100 to serve as an isolation layer between the floating gates 110 and the subsequently formed select gate 128 (FIG. 5), and to serve as a gate dielectric layer of the select gate 128.

Referring to FIG. 5, a portion of the silicon oxide layer 124, a silicon oxide layer 120 and a silicon nitride layer 122 together constitute an ONO composite spacer 126 ideal for preventing a leakage current. Thereafter, a pair of select gates 128 are formed on the outward-facing sides of the floating gates 110, covering only a portion of each floating gate 110. Each select gate 128 is isolated from the top of the corresponding floating gate 110 by a thermal oxide layer 112, and from the sidewall of the floating gate 110 by an ONO composite spacer 126. Furthermore, the select gates 128 are isolated from the substrate 100 by the gate dielectric layer 124. After a source/drain region 130 is formed on the outward-facing side of each select gate 128, a non-volatile memory having the structure according to the preferred embodiment of this invention is completed.

FIG. 5 also illustrates a schematic cross-sectional view of a non-volatile memory structure according to the embodiment of this invention. The non-volatile memory structure includes a substrate 100, a pair of floating gates 110, a high-voltage doped region 118, a pair of select gates 128 and a pair of source/drain regions 130. The substrate 100 has a pair of trenches 106 therein, each of which is disposed with a tunnel dielectric layer 108 on its surface. The floating gates 110 completely fill the trenches 106 and protrude above the surface of the substrate 100. The top of each floating gate 110 is disposed with a thermal oxide layer 112, which has a shape such that the floating gate 110 has a sharp top corner. Furthermore, the sidewall of each floating gate 110 has an ONO spacer 126 thereon. The high-voltage doped region 118 is located in the substrate 100 between the floating gates 110. The two select gates 128 are set up on the outward-facing sides of the two floating gates 110. Each select gate 128 is isolated from the top of the corresponding floating gate 110 by a thermal oxide layer 112, and from the sidewall of the floating gate 110 by an ONO spacer 126. In addition, the source/drain regions 130 are located in the substrate 100 on the outward-facing sides of the two select gates 128.

To write data into the memory cell on the left side of the non-volatile memory, a voltage large enough to switch on the underlying channel is applied to the left select gate 128, and a low voltage (for example, 0V) is applied to the left source/drain region 130. In the meantime, a high voltage is applied to the high-voltage doped region 118, so that a slightly lower high voltage is induced on the floating gate 110 for generating and attracting hot electrons, as indicated by the arrow “P” in FIG. 5. On the contrary, to erase data from the left memory cell, a positive voltage is applied to the left select gate 128 and a negative voltage is applied to the high-voltage doped region 118. With this voltage configuration, the sharp edge at the left-side top corner of the floating gate 110 undergoes a point discharge, so that the electrons trapped in the floating gate 110 are discharged to the select gate 128, as indicated by the arrow. Due to the point discharge effect of the sharp corner of the floating gate 110, a positive voltage lower than those used in ordinary non-volatile memory devices can be applied to the select gate 128 to carry out data erasure.

In this invention, the high-voltage doped region 118 that serves also as a control gate not only overlaps with the bottom portion of the floating gate 110, but also faces one side surface of the floating gate 110 separated by the tunnel dielectric layer 108. Hence, the gate-coupling ratio between the control gate and the floating gate 110 is greatly increased. Furthermore, because a portion of the floating gate 110 is buried inside the substrate 100, the height of the floating gate 110 relative to the substrate 100 is reduced. With a reduction in the height of the floating gate 110, the subsequent etching step of the select gate 128 is easier to carry out and faster to complete. Moreover, because the bottom portion of the floating gate 110 is buried deep in the substrate 100, the depth of the high-voltage doped region 118 can be increased to reduce resistivity without increasing the punch-through leakage current. Consequently, the width of the high-voltage doped region 118 can be reduced to produce a memory device with a higher degree of integration.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method for fabricating a non-volatile memory, the method comprising:
providing a substrate;
forming a mask layer over the substrate;
forming a trench in the mask layer and the substrate;
forming a tunnel dielectric layer in the trench;
forming a floating gate in the trench;
removing the mask layer;
forming a high-voltage doped region in the substrate on one side of the floating gate, the high-voltage doped region serving as a first source/drain region and a control gate; and
forming a second source/drain region in the substrate on another side of the floating gate.

2. The method of claim 1, further comprising:
forming a gate dielectric layer over the substrate; and
forming a select gate on said the other side of the floating gate, the select gate being located between the second source/drain region and the floating gate and being isolated from the substrate by the gate dielectric layer.

3. The method of claim 2, wherein the floating gate is a doped silicon layer, and the method further comprising:
performing a thermal oxidation process to form a thermal oxide layer on top of the floating gate after the floating gate is formed, wherein the thermal oxide layer has a shape such that the floating gate has sharp edges; and
forming spacers on exposed sidewalls of the floating gate after the mask layer is removed.

4. The method of claim 3, wherein the spacers comprise oxide/nitride/oxide (ONO) composite spacers.

5. The method of claim 1, wherein a bottom of the high-voltage doped region is as deep as a bottom of the floating gate.

6. The method of claim 1, wherein the high-voltage doped region extends to a region underneath the floating gate.

7. The method of claim 1, wherein the floating gate completely fills the trench.

8. A method for fabricating a non-volatile memory, the method comprising the steps of:
providing a substrate;
forming a mask layer over the substrate;
forming a pair of trenches in the mask layer and the substrate;
forming a tunnel dielectric layer in each trench;
forming a floating gate in each trench;
removing the mask layer;
forming spacers on exposed sidewalls of each floating gate;
forming a high-voltage doped region in the substrate between the trenches, the high-voltage doped region serving as a common source/drain region and a control gate;
forming a gate dielectric layer over the substrate;
forming a select gate on an outward-facing side of each floating gate, the select gate being isolated from the substrate by the gate dielectric layer; and forming a source/drain region in the substrate on an outward-facing side of each select gate.

9. The method of claim 8, wherein each floating gate is a doped silicon layer, and the method further comprising:
performing a thermal oxidation process to form a thermal oxide layer on top of each floating gate after the floating gates are formed, wherein the thermal oxide layer has a shape such that the floating gate has sharp edges, wherein
the select gates at least cover a portion of the floating gates, and upper portions of the select gates are isolated from the top of the floating gates by the thermal oxide layers and lower portions of the select gates are isolated from the sidewalls of the floating gates by the spacers.

10. The method of claim 8, wherein each spacer comprises an oxide/nitride/oxide (ONO) composite spacer.

11. The method of claim 8, wherein a bottom of the high-voltage doped region is as deep as bottoms of the floating gates.

12. The method of claim 8, wherein the high-voltage doped region extends to a region underneath each floating gate.

13. The method of claim 8, wherein each floating gate completely fills the corresponding trench.

14. A non-volatile memory, comprising:
a substrate with a trench therein;
a tunnel dielectric layer in the trench;
a floating gate that completely fills the trench and protrudes beyond the substrate;
a high-voltage doped region in the substrate on one side of the floating gate, serving as a first source/drain region and a control gate; and
a second source/drain region in the substrate on an other side of the floating gate.

15. The non-volatile memory of claim 14, wherein the memory further comprises:
a gate dielectric layer over the substrate;
a select gate located on said other side of the floating gate between the floating gate and the second source/drain region, being isolated from the substrate by the gate dielectric layer.

16. The non-volatile memory of claim 15, wherein the floating gate is a doped silicon layer with an oxide layer on its top portion and spacers on its sidewalls, wherein the oxide layer has a shape such that the floating gate has sharp edges, and
the select gate at least covers a portion of the floating gate, and an upper portion of the select gate is isolated from the top of the floating gate by the oxide layer and a lower portion of the select gate is isolated from the sidewall of the floating gate by the spacer.

17. The non-volatile memory of claim 16, wherein the spacers comprise oxide/nitride/oxide (ONO) composite spacers.

18. The non-volatile memory of claim 14, wherein a bottom of the high-voltage doped region is as deep as a bottom of the floating gate.

19. The non-volatile memory of claim 14, wherein the high-voltage doped region extends to a region underneath the floating gate.

20. A non-volatile memory, comprising:
a substrate with a pair of trenches therein;
a tunnel dielectric layer in each trench;
a pair of floating gates each filling a trench and protruding beyond the substrate, wherein sidewalls of each floating gate is disposed with spacers;
a high-voltage doped region in the substrate between the floating gates, serving as a common source/drain region and a control gate;
a pair of select gates on outward-facing sides of the floating gates, wherein each select gate is isolated from the substrate by a gate dielectric layer; and
a pair of source/drain regions in the substrate on outward-facing sides of the select gates.

21. The non-volatile memory of claim 20, wherein each floating gate is a doped polysilicon layer with a thermal oxidation layer on itstop portion, wherein the thermal oxide layer has a shape such that each floating gate has sharp edges, and
the select gates at least covers a portion of the floating gates, and upper portions of the select gates are isolated from the top of the floating gates by the thermal oxidation layers and lower portions of the select gates are isolated from the sidewalls of the floating gates by the spacers.

22. The non-volatile memory of claim 20, wherein each spacer comprises an oxide/nitride/oxide (ONO) composite spacer.

23. The non-volatile memory of claim 20, wherein a bottom the high-voltage doped region is as deep as bottoms of the floating gates.

24. The non-volatile memory of claim 20, wherein the high-voltage doped region extends to a region underneath each floating gate.
